(19) United States
(12) Patent Application Publication
(10) Pub. No.: US 2010/0289101 A1
(43) Pub. Date: Nov. 18, 2010

(54) IMAGE SENSOR

(75) Inventors: Jérôme Vaillant, Grenoble (FR); Flavien Hirigoyen, Grenoble (FR)

Correspondence Address: STMicroelectronics Inc.;c/o WOLF, GREENFIELD & SACKS, P.C., 600 Atlantic Avenue, BOSTON, MA, 02210-2206, US

(73) Assignee: STMicroelectronics S.A., Montrouge (FR)

(21) Appl. No.: 12/779,530

(22) Filed: May 13, 2010

(30) Foreign Application Priority Data
May 15, 2009 (FR) 09/53245

(51) Int. Cl. H01L 31/0232; H01L 31/18

(52) U.S. Cl. 257/432; 438/69; 257/E31.127; 257/E31.001

(57) ABSTRACT

An image sensor including an array of pixels, wherein each pixel includes, in a vertical stack: a central photosensitive area; a stack of interconnects on top of the periphery of the photosensitive area, extending upwards up to a first height; a filtering layer on top of the photosensitive area, extending upwards from a height lower than the first height; and a microlens overlying the filtering layer in vertical projection, the optical axis of this microlens being such that the light rays received by the pixel reach the photosensitive area, substantially at its center.

### CROSS REFERENCE TO RELATED APPLICATIONS

This application claims the priority benefit of French patent application number 09/53245, filed on May 15, 2009, entitled “IMAGE SENSOR,” which is hereby incorporated by reference to the maximum extent allowable by law.

### BACKGROUND OF THE INVENTION

1. Field of the Invention

The present invention relates to image sensors, and more specifically to the structure of the pixels of an image sensor.

2. Discussion of the Related Art

FIG. 1 is a very simplified cross-section view of a square or rectangular image sensor 1 assembled opposite to an objective lens 3, substantially at the level of its focal plane. Sensor 1 is essentially formed of an array of pixels formed in a semiconductor substrate. A pixel 5 and a pixel 7, respectively arranged at the center and at the border of sensor 1, are shown as an example. As illustrated by the light paths shown in full lines and in dotted lines, the pixels placed at the center of the sensor, such as pixel 5, receive rays centered on an angle of incidence close to 0°. Conversely, the pixels placed at the border of the sensor, and especially in corners, such as pixel 7, receive rays centered on a high angle of incidence.

Such sensors are used in many devices, for example, mobile phones. The diameter of the objective lens is, for example, on the order of from 2 to 3 mm, the focal distance of the objective lens is on the order of from 6 to 10 mm, and the thickness of the substrate forming sensor 1 is on the order of from 0.2 to 0.5 mm. For bulk reasons, it is desirable to reduce the distance between the objective lens and the sensor. This results in an increase in the average angle of incidences for the pixels located at the border of the sensor. As an example, the average angle of incidence of the rays received by pixel 7 may exceed 30°.

FIG. 2 is a cross-section view showing the structure of a pixel 21 of an image sensor. Each pixel is associated with a portion of the surface of a substrate 23 which, as seen from above, is generally square- or rectangle-shaped. Pixel 21 comprises an active photosensitive area 25 formed in the upper part of this substrate portion, generally corresponding to a photodiode capable of storing an amount of electric charge which depends on the received light intensity. Photosensitive area 25 does not cover the entire substrate portion associated with pixel 21. Indeed, a portion of the surface is reserved to devices (not shown) for addressing the pixel and reading from it. Photosensitive area 25 generally covers from 30 to 50% of the substrate surface area associated with pixel 21.

Substrate 23 is covered with a stack of insulating and transparent layers 27, for example formed of silicon oxide. Conductive tracks 29, formed at the surface of substrate 23 and between adjacent insulating layers, and conductive vias 31, formed through the insulating layers, especially enable addressing the pixels and to collect electric signals. Tracks 29 and vias 31 are arranged so as not to cover photosensitive area 25. Further, in a color sensor, a color filtering element 33, for example, an organic filter, is arranged above the stack of insulating layers, opposite to the portion of substrate 23 associated with the pixel. Filter 33 is generally covered with an intermediary leveling layer 35, which defines a surface of exposure to light. This layer 35 especially enables obtaining a planar surface above the filters. As an example, the thickness of the stack of insulating layers 27, of tracks and vias 29 and 31, and of filter 33 is on the order of from 1 to 5 μm.

To concentrate the light intensity received at the surface of pixel 21 towards photosensitive area 25, a microlens 37 is arranged at the surface of intermediary layer 35, in front of the substrate portion associated with pixel 21.

Microlenses 37 are generally obtained by covering intermediary layer 35 with a resin layer, by etching separate resin blocks, each resin block being formed substantially in front of the substrate portion associated with a pixel, and by heating the resin blocks. Each resin block then tends to deform by flowing, until it forms a convex external surface.

The path of the light rays shown as an example in full lines corresponds to the case of an average angle of incidence close to zero, that is, to the rays received by a pixel located at the center of the sensor. Microlens 37 makes such rays converge towards photosensitive area 25.

FIG. 3A is identical to FIG. 2, but for the path of the light rays shown in full lines as an example. The path shown in FIG. 3A corresponds to the case of a non-zero average angle of incidence, that is, to a pixel located in the peripheral area of the sensor. The microlens focusing point for such rays is located outside of the photosensitive area, which translates as an alteration of the sensitivity of the sensor.

It is provided, for each pixel, according to its position on the sensor, to offset the associated microlens and color filter so that the received light rays converge towards the corresponding photosensitive area and fully cross the filter associated with this area.

FIG. 3B is a cross-section view of a pixel 41 located in a peripheral area of an image sensor and intended to receive rays of non-zero average angle of incidence. Pixel 41 is identical to pixel 21 of FIGS. 2 and 3A but its color filter 43 and its microlens 45 are offset with respect to its photosensitive area 47. This offset is calculated according to the position of the pixel on the sensor, to the thickness of the dielectric, and to the refractive indexes, so that the central ray reaches the center of the photosensitive area. Thus, pixel 41 is capable of receiving light rays of non-zero average angle of incidence.

Generally, it is desirable to decrease the thickness of the materials located above each photosensitive area, especially to improve the sensitivity of the sensor.

FIG. 4 is a cross-section view schematically and partially showing an image sensor formed of an array of pixels 61 of the same structures as pixels 21 and 41 described in relation with FIGS. 2 and 3B. Semiconductor substrate 63 in which photosensitive areas 65 of the pixels are formed is covered with a stack 67 of insulating and transparent layers. Conductive interconnect tracks are formed between the insulating layers. Several successive interconnect levels, seven in the shown example, M1 to M7, are provided for the proper operation of the sensor, M1 to M7 being respectively the closest level and the most remote level from substrate 63. In this example, only the two lower levels M1 and M2 are used for the pixel addressing and reading. Thus, it is provided to arrange the conductive tracks of levels M3 to M7 at the sensor periphery, so that they do not cover the substrate portion in which the pixel array is formed. It is further provided to remove the insulating layer portions corresponding to levels M3 to M7 and to cover the substrate portion in which the pixel array is formed. A cavity 69 is thus formed in stack 67, opposite to the pixel array. The bottom of cavity 69, for example, corresponds to the insulating layer covering the conductive tracks of interconnect level M2. On the bottom of cavity 69 are formed an array of filters 71 and a corresponding array of microlenses 73. Thus, the provision of cavity 69 enables decreasing the distance between microlens 73 and photosensitive area 65 of each pixel. However, this distance remains non-negligible.

### SUMMARY OF THE INVENTION

Thus, an object of an embodiment of the present invention is to provide a pixel structure which overcomes all or at least part of the disadvantages of prior art.

An embodiment of the present invention provides a pixel structure in which the distance between the microlens and the associated photosensitive substrate area is decreased with respect to prior art solutions.

An object of an embodiment of the present invention is to provide such a structure which can be easily formed.

Thus, an embodiment of the present invention provides an image sensor comprising an array of pixels, wherein each pixel comprises, in a vertical stack: a central photosensitive area; a stack of interconnects on top of the periphery of the photosensitive area, extending upwards up to a first height; a filtering layer on top of the photosensitive area, extending upwards from a height lower than the first height; and a microlens overlying the filtering layer in vertical projection, the optical axis of this microlens being such that the light rays received by the pixel reach the photosensitive area, substantially at its center.

According to an embodiment of the present invention, the filtering layer is formed of a colored organic resin.

According to an embodiment of the present invention, the thickness between the surface of the photosensitive area and the microlens ranges between 0.5 μm and 5 μm.

According to an embodiment of the present invention, insulating layers are interposed between the successive interconnects.

According to an embodiment of the present invention, the insulating layers are formed of silicon oxide.

According to an embodiment of the present invention, the microlenses are formed in a resist layer by grey level masking, exposure by illumination of the mask, and development, wherein the resist thickness is inversely proportional to the grey level of the mask portion covering it.

The foregoing objects, features, and advantages of the present invention will be discussed in detail in the following non-limiting description of specific embodiments in connection with the accompanying drawings.

### BRIEF DESCRIPTION OF THE DRAWINGS

FIG. 1, previously described, is a cross-section view of an image sensor assembled opposite to an objective lens;

FIG. 2, previously described, is a cross-section view showing the structure of an image sensor pixel;

FIG. 3A, previously described, illustrates the path of the light rays received by pixels located at the sensor periphery;

FIG. 3B, previously described, is a cross-section view of a pixel located at the sensor periphery;

FIG. 4, previously described, is a cross-section view schematically and partially showing an image sensor;

FIG. 5A is a cross-section view of an embodiment of a pixel;

FIG. 5B illustrates a variation of the pixel of FIG. 5A; and

FIG. 6 is a cross-section view showing the structure of an image sensor pixel according to an embodiment of the present invention.

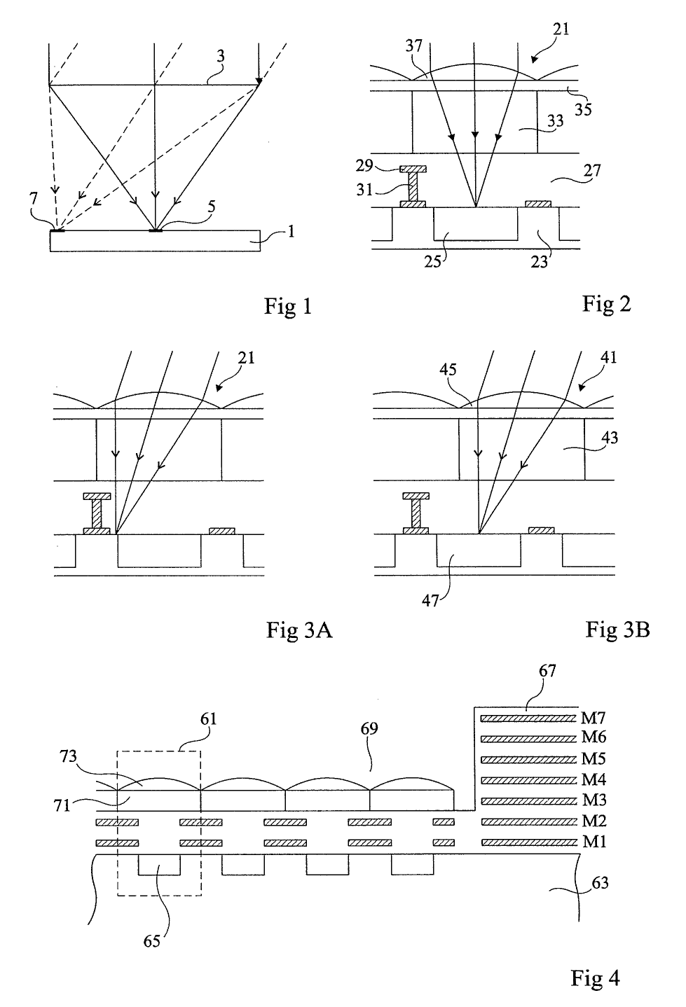

### DETAILED DESCRIPTION

For clarity, the same elements have been designated with the same reference numerals in the different drawings and, further, as usual in the representation of integrated circuits, the various drawings are not to scale.

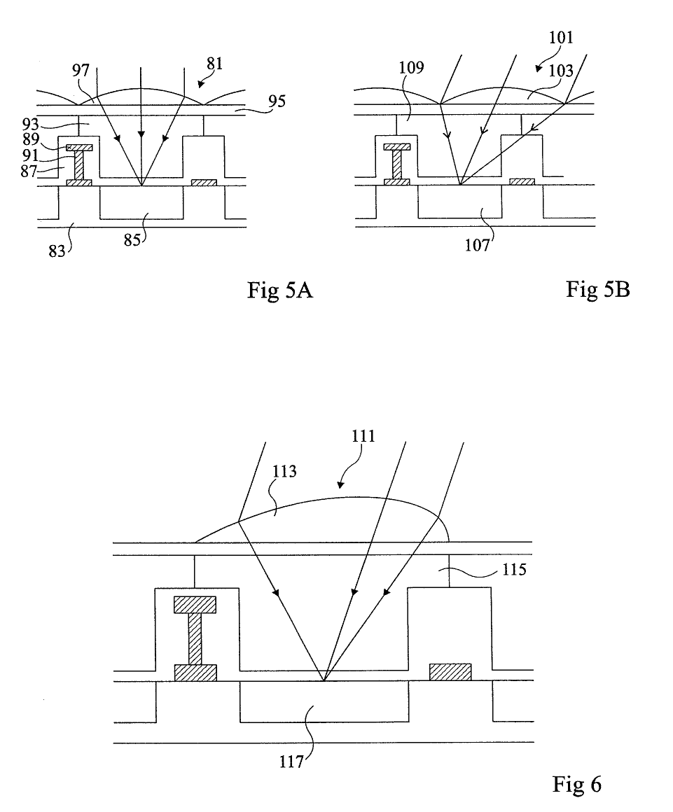

FIG. 5A is a cross-section view showing the structure of a pixel 81 of an image sensor. Each pixel is associated with a portion of the surface of a substrate 83 which, in top view, is generally square- or rectangle shaped. Pixel 81 comprises an active photosensitive area 85 formed in the upper part of this substrate portion, generally corresponding to a photodiode capable of storing an amount of electric charge which depends on the received light intensity.

Photosensitive area 85 does not cover the entire substrate portion associated with pixel 81. Indeed, part of the surface is reserved to devices (not shown) for addressing the pixel and reading from it. Photosensitive area 85, for example, covers from 30 to 50% of the substrate surface associated with pixel 81.

Substrate 83 is covered with a stack of insulating and transparent layers 87, for example, formed of silicon oxide. Conductive tracks 89, formed at the surface of substrate 83 and between adjacent insulating layers, and conductive vias 91, formed through the insulating layers, especially enable addressing the pixels and collecting electric signals. Tracks 89 and vias 91 are arranged to avoid masking photosensitive area 85.

According to an aspect of the present invention, a cavity dug into the stack of transparent insulating layers 87 opposite to photosensitive area 85 is provided. The bottom of this cavity is, for example, located at the same level as the interconnect level closest to the substrate. A color filtering element 93, for example, an organic filter, extends upwards from the bottom of the above-mentioned cavity. Filter 93 may extend above stack 87, opposite to the portion of substrate 83 associated with the pixel. Filter 93 is generally covered with an intermediary equalization layer 95, which defines a surface of exposure to light. Layer 95 especially enables obtaining a planar surface above the filters.

To concentrate the light intensity received at the surface of pixel 81 towards photosensitive area 85, a microlens 97 is arranged at the surface of intermediary layer 95, opposite to the substrate portion associated with the pixel.

The path of the light rays shown in full lines as an example corresponds to the case of an average angle of incidence close to zero, that is, to the rays received by a pixel located at the center of the sensor. Microlens 97 makes such rays converge towards photosensitive area 85. Thus, pixel 81 is capable of being positioned at the center of the sensor.

FIG. 5B is a cross-section view of a pixel 101 located in a peripheral area of an image sensor and intended to receive rays of non-zero average angle of incidence. Pixel 101 is identical to pixel 81 of FIG. 5A but its microlens 103 is offset with respect to photosensitive area 107. The offset depends on the position of the pixel on the sensor and is such that the received light rays converge towards area 107. Color filter 109 being arranged in the cavity dug into the stack of insulating layers, it is difficult to offset it with respect to the microlens as in the case of FIG. 3B.

The path of the light rays shown in full lines as an example corresponds to the case of a non-zero angle of incidence. It can be observed that some rays (to the right of the drawing) only cross a very small thickness of filter 109 before reaching photosensitive area 107. Further, some rays partially cross the color filter of the neighboring filter. This results from the impossibility of displacing the filter like the microlens, in a direction parallel to said lens, and is amplified when the average angle of incidence of the received rays increases. Rays may further reflect on the metal tracks and vias, which disturbs the signal collected by the photosensitive area.

According to an aspect of the present invention, it is provided to arrange asymmetrical microlenses opposite to the color filter so that the received rays converge towards the photosensitive area and totally cross the filter.

FIG. 6 is a cross-section view showing the structure of a pixel 111 located in a peripheral area of an image sensor and intended to receive rays of non-zero average angle of incidence. Sensor 111 is identical to sensor 101 of FIG. 5B except for its microlens 113 which differs from microlens 103 of pixel 101. Conversely to microlens 103, microlens 113 is arranged entirely above color filter 115, itself centered on photosensitive area 117. Further, microlens 113 is asymmetrical. The optical axis of microlens 113 runs through the point of maximum thickness which then does not correspond to the center of the pixel. The offset of the optical axis is calculated according to the position of the pixel on the sensor, to the dielectric thickness, and to the refractive indexes, so that the received rays converge towards photosensitive area 117 as illustrated by the path shown in full lines. Thus, pixel 111 is capable of being positioned at the sensor periphery and of receiving light rays of non-zero average angle of incidence. All the light rays fully cross the filter, whatever the point of incidence on the microlens.

There exist various methods to form asymmetrical microlenses, such as the grey level etching. This method especially comprises, in a first step, depositing a resist layer on the surface of exposure to light of a sensor. In another step, the resist is exposed by means of a grey level mask. Thus, the intensity of the irradiation received by the resist varies in space according to the position in the mask. After this step, the resist is developed. The sensitivity of the resist to the development is proportional to the intensity of the irradiation received during the exposure. Thus, the amount of resin remaining after the development is inversely proportional to the grey level of the mask.

Such a method may further comprise anneal steps, not described hereabove. It is thus possible to “sculpt” microlenses of adapted shape for all the sensor pixels.

According to an advantage of the present invention, the provided pixel structure enables decreasing the distance between the microlens and the photosensitive area, thus increasing the sensitivity of the sensor.

According to an advantage of the present invention, all the asymmetrical microlenses of the sensor may be formed simultaneously according to known manufacturing methods.

Various specific embodiments of the present invention have been described. Various alterations and modifications will occur to those skilled in the art. In particular, the present invention is not restricted to the described or shown examples in which two interconnect levels are used for the pixel addressing and reading. It will be within the abilities of those skilled in the art to implement the desired operation whatever the number of interconnect levels formed in the sensor. Further, the present invention is not restricted to the sole sensor for which the asymmetrical microlenses are manufactured by the above-described grey level etch method. Other methods for forming asymmetrical microlenses may be used, for example, molding methods. Further, the above-described pixel structures comprise a color filtering element formed of an organic resin. The present invention is not restricted to this specific case. It will be within the abilities of those skilled in the art to implement the desired operation whatever the type of color filter used.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. An image sensor comprising an array of pixels, wherein each pixel other than one or more central pixels comprises, in a vertical stack:
a central photosensitive area;
a stack of interconnects on top of the periphery of the photosensitive area, extending upwards up to a first height;
a filtering layer on top of the photosensitive area, extending upwards from a height lower than the first height; and
an asymmetrical microlens overlying the filtering layer in vertical projection and centered on the filtering layer, the optical axis of this microlens being such that the light rays received by the pixel reach the photosensitive area, substantially at its center.

2. The image sensor of claim 1, wherein the filtering layer is formed of a colored organic resin.

3. The image sensor of claim 1, wherein a thickness between the surface of the photosensitive area and the microlens ranges between 0.5 μm and 5 μm.

4. The image sensor of claim 1, wherein insulating layers are interposed between the successive interconnects.

5. The image sensor of claim 4, wherein the insulating layers are formed of silicon oxide.

6. A method of fabricating the image sensor of claim 1, wherein the microlenses are formed in a photosensitive resist layer by grey level masking, exposure by illumination of the mask, and development, the photosensitive resist thickness being inversely proportional to the grey level of the mask portion covering it.
